(19) United States
(12) Patent Application Publication
(10) Pub. No.: US 2012/0234388 A1
(43) Pub. Date: Sep. 20, 2012

(54) ASSEMBLY FOR ELECTRICAL BREAKDOWN PROTECTION FOR HIGH CURRENT, NON-ELONGATE SOLAR CELLS WITH ELECTRICALLY CONDUCTIVE SUBSTRATES

(76) Inventors: Robert Stancel, Los Altos Hills, CA (US); Joseph Jalbert, San Jose, CA (US)

(21) Appl. No.: 13/392,503

(22) PCT Filed: Aug. 26, 2010
(86) PCT No.: PCT/US2010/046877

§ 371 Date: Jun. 6, 2012

Related U.S. Application Data
(60) Provisional application No. 61/237,295, filed on Aug. 26, 2009.
(60) Provisional application No. 61/247,526, filed on Sep. 30, 2009.

(51) Int. Cl. H01L 31/02; H01L 31/024; H01L 31/18

(52) U.S. Cl. 136/259; 438/62; 136/252; 257/E31.11

(57) ABSTRACT

Methods and devices are provided for avalanche breakdown in a thin-film solar cell. In one embodiment, a method of breakdown protection assembly comprises providing a single reel of material which is pre-cut in a pattern so that a first portion of the material can be overlapped to a second portion of material to sandwich a breakdown protection device therebetween

### FIELD OF THE INVENTION

This invention relates to using a photovoltaic device with electrical breakdown protection.

### BACKGROUND OF THE INVENTION

A central challenge in cost-effectively providing breakdown protection in a photovoltaic device relates in part to the assembly processes used for photovoltaic cell manufacturing and the high cost associated with traditional diode devices being appropriately packaged for use in the solar industry. The size of the traditional packaging of diodes or other protection devices make them cumbersome to incorporate into the module at the cell level, and furthermore, such packaging introduces a variety of complexities for integrating such protection devices into traditional solar cells.

Furthermore, thin-film solar cells such as those comprised of CIGS or other IB-IIIA-VIA material have often not needed diodes as these cells when made on metal foil and were able to withstand hot spots without comprising the entire module. However, even with these cells, some issues remain that may be addressed by having breakdown protection.

Thus, there is a need for improved methods and devices for incorporating electrical breakdown protection device into photovoltaic cells.

### SUMMARY OF THE INVENTION

The disadvantages associated with the prior art are overcome by embodiments of the present invention.

In one embodiment, a thin film solar cell with electrical breakdown protection.

Optionally, the device comprises a non-elongated, non-silicon thin-film solar cell using an electrically conductive foil substrate wherein the foil substrate carries current when the cell is forward biased, the substrate having a ratio of width to length greater than about 0.5 along an axis of current flow, and when exposed to light at AM 1.5G, the solar cell has an Impp greater than about 4 amps; an avalanche breakdown protection assembly to prevent the avalanche breakdown at the one or more locations by directing current through the protection unit.

Optionally, the device comprises an in-solar cell diode

Optionally, the device comprises packaging with top and bottom heat sink connectors, wherein the heat sinks are different layers of the same cell.

Optionally, the device comprises packaging with top and bottom heat sink connectors, wherein the heat sinks are different layers of different cells.

Optionally, the device comprises a total vertical height is about 180 to 500 microns or less

Optionally, the device comprises stack height is about 300 to 400 microns or less

Optionally, the device comprises a first area that is provided with a first material and a second area that is provided with a second material, wherein the first and second materials are different from one another, and wherein the first and second materials are selected from (a) materials that are electrically conductive, (b) materials that do not bond well to each other, (c) an interface material therebetween

said composition at least partially filling a cavity on the tab

Optionally, the device comprises a device for implantation in a solar cell comprising a diode, a first heat sink attachment having a triggerable adhesive property that allows the implantable device to adhere when exposed to a stimulus.

Optionally, the device comprises a tab having a bulk sub-region beneath the surface is activated to be become a solderable joint forming area and another area that is not substantially coated and not solderable when activated.

In another aspect, a method of breakdown protection assembly comprising:

providing a single reel of material which is pre-cut in a pattern so that a first portion of the material can be overlapped to a second portion of material to sandwich a breakdown protection device therebetween.

In one aspect, a solar module is described comprising: a solar cell string including a plurality of solar cells including a first solar cell and a second solar cell, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell; a bypass diode device attached to the solar cell string, the bypass diode device including a bypass diode having a first and second leads, and first and second conductive strips each electrically connected at one end to one of the first and second leads respectively and each electrically connected at another end to a first conductive substrate of the first solar cell and a second conductive substrate of the second solar cell, respectively; an encapsulant having a frontside and a backside that encapsulates the solar cell string and the bypass diode device; and a protective shell sealing the encapsulated string, the protective shell including a transparent front protective layer, a back protective layer and a moisture barrier seal extending between and sealing edges of the transparent front protective layer and the back protective layer, wherein the transparent front protective sheet is placed over the light receiving side of the plurality solar cells and the frontside of the encapsulant and the back protective sheet is placed under the first and second conductive substrates, the by pass diode device and the backside of the encapsulant such that the bypass diode is located between the back protective sheet and housed in openings of conductive substrates of the plurality of solar cells.

In another aspect, a method of manufacturing a solar module is described comprising: providing a front protective layer having a front surface and a back surface, wherein the front protective layer is transparent; placing a first encapsulant layer over the back surface of the front protective layer; placing a solar cell string over the first encapsulant layer, wherein the solar cell string includes a plurality of solar cells, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell, and wherein the light receiving side of the solar cells face the first encapsulant layer; attaching a bypass diode device to the solar cell string, the bypass diode device including a first conductive strip and a second conductive strip each attached at one end to respective first and second leads of a bypass diode, wherein the bypass diode is electrically connected to a first conductive substrate of a first solar cell and a second conductive substrate of a second solar cell of the plurality of solar cells by the first conductive strip and the second conductive strip, respectively; placing a second encapsulant layer over the bypass diode device and the conductive substrates of the plurality of solar cells; placing a back protective sheet over the second encapsulant layer and sealing a peripheral gap between the periphery of the front protective sheet and the back protective sheet with a moisture barrier edge sealant, and thereby forming a pre-module structure; and subjecting the pre-module structure to heat and pressure to form the solar module.

In one embodiment, the present invention, due to its use of a flexible structure that utilizes solar cells that are made on a metallic foil substrate, allows use of the metallic foil substrate as the heat sink for the bypass diodes. Thus, bypass diodes placed over the back surface of the metallic substrates of the solar cells may be thermally coupled to the solar cell substrates and any heat generated by the bypass diode can easily be dissipated to the large area solar cell and eventually to outside of the module. This also allows usage of bypass diodes that are sized to correspond to the module current rating, or some small percentage greater than the module current rating for reliability reasons, such as 10% or 20% larger. It should be noted that the typical size of the solar cells made on flexible substrates as described herein are larger than about 100 cm.sup.2, whereas the typical size of the bypass diodes that correspond to the module current rating is less than 1 cm.sup.2. Therefore, the cell provides excellent heat sink properties to the bypass diode. This increases the long term reliability of the module.

A further understanding of the nature and advantages of the invention will become apparent by reference to the remaining portions of the specification and drawings.

### BRIEF DESCRIPTION OF THE DRAWINGS

FIG. 1 shows a cross-sectional view of one portion of a solar cell according to one embodiment of the present invention.

FIG. 2 shows a plan view of an underside of a one embodiment of a solar cell.

FIG. 3 shows a plan view of a breakdown resistance assembly according to one embodiment of the present invention.

FIG. 4 shows a cross-sectional view of one portion of a solar cell according to one embodiment of the present invention.

FIG. 5 shows a top down view of a breakdown resistance assembly according to one embodiment of the present invention.

FIGS. 6 through 10 show top down views of various breakdown resistance assemblies according to embodiments of the present invention.

FIGS. 11 through 14 show continuous workpieces from which portions are formed of a breakdown resistance assembly according to one embodiment of the present invention.

FIGS. 15 through 17 show a variety of techniques of bring elements together to form a breakdown resistance assembly according to one embodiment of the present invention.

FIGS. 18 through 21 show formation of elongate workpieces from which portions are formed of a breakdown resistance assembly according to one embodiment of the present invention.

FIGS. 22 through 23 show techniques for forming a breakdown resistance assembly according to one embodiment of the present invention.

FIGS. 24 through 25 show techniques for connecting solar cells using at least one breakdown resistance assembly according to one embodiment of the present invention.

FIG. 26 a breakdown resistance assembly with a void minimizing element according to one embodiment of the present invention.

FIG. 27 shows one embodiment of a solar cell suitable for use with embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

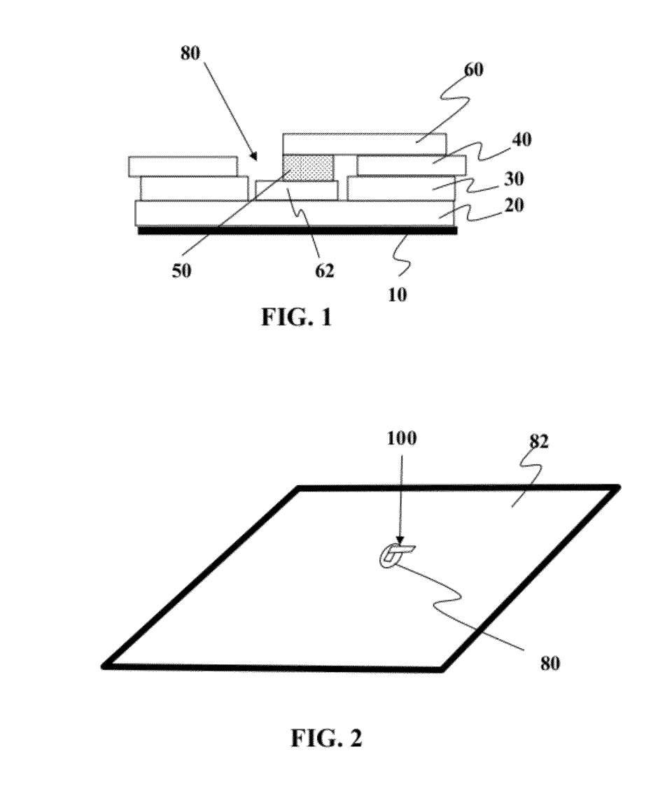

Referring now to FIG. 1, one embodiment of a diode positioned fully within a thin film solar cell is shown. It should be understood that in some embodiments, the diode is only partially contained within the solar cell. FIG. 1 shows a cross-section view of a solar cell that the inverted so that the back side is now on top. This is done to ease manufacturing, but the present invention is not limited to such a configuration. During use, the side with the photovoltaic absorber will typically be facing upward. Embodiments using tandem cell or other configurations are not excluded. FIG. 1 shows that a thin-film absorber 10 is on the underside of a flexible substrate 20 (which in this embodiment is a metal foil). The metal foil may be but is not limited to steel, stainless steel, aluminum, copper, their alloys, metallized polymers, single or multiple combinations of the foregoing, or the like. In this embodiment, an electrically insulating layer 30 is provided along with a backside metal foil 40. A diode 50 such as but not limited to a bare die diode is provided in the structure. A conductive metal layer 60 is provided over the diode 50. A similar conductive layer 62 is provided on the underside of the diode 50. A first electrical connection material is provided between the diode 50 and layer 20. A second electrical connection material is provided between the diode 50 and the layer 60. This structure is non-limiting and it should be understood that the diode may be positioned at other locations in the thin film solar cell. The layers 20 and 40, in one embodiment, are metal foil layers that act as heat sinks for the assembly 100.

Referring to FIG. 2, according to at least one embodiment of the present invention, the opening 80 in the underside of the solar cell 82 for the diode or other breakdown protection device may be formed by a variety of techniques. FIG. 2 shows that the assembly 100 may be inserted into the opening 80 to provide the desired breakdown protection. In one embodiment, the opening, which can extend down to multiple layers of the solar cell, allows for the entire assembly, except for the thickness of the upper tab 60 to be fully contained in the opening. After assembly, the opening can be filled with encapsulant during lamination of the module, or optionally, prefilled with encapsulant after attachment of the assembly 100, or optionally, not filled.

The packaging in one embodiment, creates an ultra-low profile assembly without the bulk of traditional die packaging and without encapsulant, as the entire module or panel will have an encapsulant layer when the module is laminated.

### Butterfly Diode Packaging

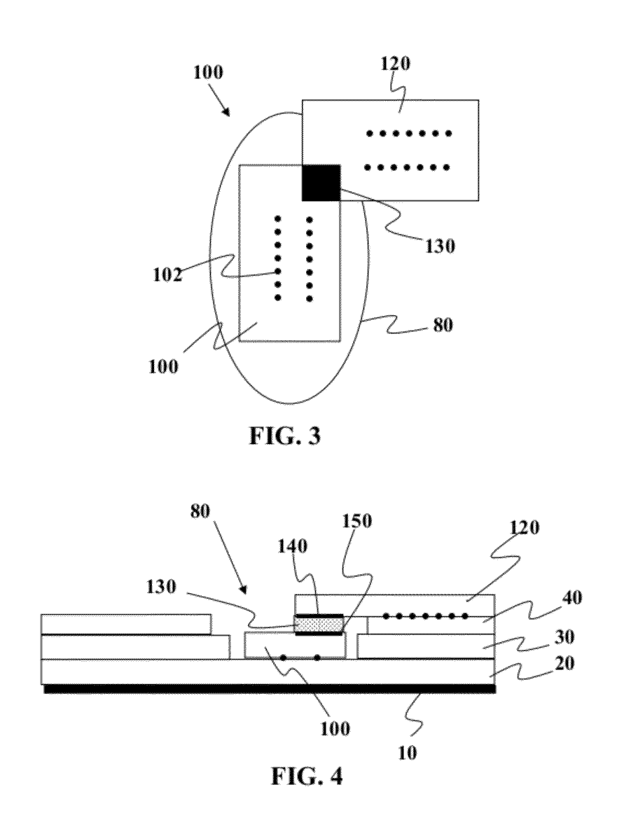

Referring now to FIG. 3, one embodiment of a breakdown protection assembly 100 will now be described. The term “butterfly” is a term of art used to figuratively describe the appearance of some embodiments of the assemblies. This assembly 100 can improve throughput during cell manufacturing and also enable other attachment techniques to be used. The assembly 100 can be formed in a process separate from the connection of the cells into strings during module assembly. The assembly can be incorporated directed into the cell or optionally, as part of the connection between two or more cells. As seen in this embodiment of FIG. 3, a double row of attachment areas 102 are provided on each metal tab 110 and 120. These attachment areas 102 may be spot welds, laser welds, ultrasonic welds, or the like. Some embodiments may optionally use electrically conductive adhesives with or without the welds. Other methods or attachment techniques are not excluded so long as electrical and thermal contact is established between the tabs 110 and 120 with the solar cell and with the breakdown protection device 130 sandwiched between tabs 110 and 120. Some embodiments may use continuous areas of attachment and this embodiment herein uses discrete attachment areas 102. Optionally, some embodiments may use a single row of welds, but to minimize the risk of tear out, the welds may be double rowed or otherwise laid out in a pre-configured pattern on the tabs 110 or 120 to increase area of contact. Thus, as seen in some embodiments, some areas of the tab 110 or 120 are fully attached, while other areas remain in slidable contact. This can act as a strain relief during temperature cycling that a solar cell can experience during daily use.

By way of nonlimiting example, the tabs 110 and 120 in this embodiment are configured wider than the diode since it is desirable for handling purposes and to have space for the welds or attachment areas 120. The present design is offset to allow for wide strips or tabs 110 and 120, but also not have the tabs 110 and 120 overlap each other when sandwiching the breakdown protection device 130 therebetween. In one embodiment, the tab 110 is a wide enough strip to weld or attach it to the cell, but other than the area occupied by the breakdown protection device 130, one does not want excess overlap with the tab 120, as there may be a risk of electrical shorting. This is due in part to the relatively small height separation such as 0.1 mm between the two tabs 110 and 120. There is a risk that during lamination, soldering, or assembly, the tabs 110 and 120 may press together if there are overhanging areas. In one embodiment, the tabs may be about 1-3 mm wide and about 2-10 mm long. Optionally, some embodiments may have tabs about 1-10 mm wide and about 2-50 mm long. Optionally, some embodiments may have tabs about 1-30 mm wide and about 2 mm to maximum length of the cell long. In one embodiment, the ratio of the thickness of the simultaneously thermal and electrical connectors 110 to the thickness of the bare die is about 1:10 to about 1:5. Optionally, the ratio of the thickness of the simultaneously thermal and electrical connectors 110 to the thickness of the bare die is about 1:12 to about 1:6. This allows for the strain or stress from thermal cycling and CTE to be absorbed by the tab 110 and/or 120. Thus the yield strength of the tab 110 in one embodiment, can be configured to be less than the yield strength of the solder joint between the die and the tab. Optionally, the yield strength of the tab in one embodiment, can be configured to be less than the yield strength of the bare die. Optionally, the yield strength of the tab in one embodiment, can be configured to be less than the fatigue limit of bare die after temperature cycling 500 cycles from −40 to 85 C. Optionally, the yield strength of the tab in one embodiment, can be configured to be less than the fatigue limit of solder joint between the tab and a surface of the die after temperature cycling 500 cycles from −40 to 85 C. This allows the tab to be a strain relief for the solder joint. In one embodiment, this strain relief is achieved by the thinness of the material of the tab. Thus, stress yields occur in the tab, not the die or the solder joint. In one embodiment, the thickness of the tabs may be in the range of about 0.100 mm to about 0.070 mm thick. Optionally, the thickness of the tabs may be in the range of about 0.120 mm to 0.050 mm thick. Optionally, the thickness of the tabs may be in the range of about 0.050 mm to 0.075 mm thick. Optionally, the thickness of the tabs may be in the range of about 0.040 mm to 0.060 mm thick. Optionally, the thickness of the tabs may be in the range of about 0.010 mm to 0.060 mm thick. Total stack height with all layers and the die can be about 0.200 mm to about 0.500 mm in vertical height.

In one embodiment, the tabs 110 and 120 is typically selected to be material this compatible with the material used for the cell. In one example, the material for the tabs may have a coefficient of thermal expansion that is the same or similar to the cell material. By way of nonlimiting example, the tab may be made of steel, carbon steel, stainless steel, aluminum, copper, molybdenum, their alloys, metallized polymers or plastics, single or multiple combinations of the foregoing, or the like. In one embodiment, if the heat sink layers in the cell are made of aluminum, the tabs 110 and 120 can also be made of aluminum such as but not limited to 1000 series aluminum.

It should be understood that in many embodiments, the tabs 110 and 120 are at least partially cladded, plated, mechanically pressed, or otherwise provided with an electrically conductive material on one side. In one embodiment, this treated area is typically shaped to match the area where the breakdown protection device 130 will be placed or sandwiched between the tabs 110 and 120. Optionally, a greater area or only select areas are cladded or treated within the area where the breakdown protection device 130 will be placed. In one embodiment, the tabs 110 and 120 are cladded directly with solder. Optionally, they may be cladded with a material that is not solder, but can be soldered to or has good electrical conductivity. In one embodiment, the system may comprise of a copper layer that is an interface layer between an aluminum tab and a solder layer. Some embodiments may optionally recess a portion of the tab 110 so that the interface layer and the solder layer remain within the shape of the original tab (which may be a rectangular profile).

For example, if the tabs 110 and 120 comprise of aluminum, a cladded/plated different metal is plated or otherwise attached to the aluminum foil. Then aluminum is welded to cell. For an aluminum foil tab, the aluminum is cleaned first and then the cladding or plated material is applied before a native oxide of aluminum can form. The cladding using a different material from that of the tab, creates an interface surface to facilitate the transition from the material of the tab to that of the die, which would otherwise be incompatible. In one embodiment, this interface surface is a non-solder, electrically conductive material.

Preferably, but not necessarily, the tabs 110 and 120 can come presoldered or with solder material thereon. One non-limiting example will put down nickel, then copper, then tin-silver solder or some combination thereof. Of course, it should be understood that any of a variety of types of solders may be used and the present embodiment is not limited to any particular one. For example, some embodiments may use tin, copper, silver, bismuth, indium, zinc, antimony, or other metal based solders. The solder may include flux or it may be flux free. The assembly of the tabs 110, 120 and the breakdown protection device 130 occurs when the assembly is pressed together, heated and thus soldered to form a breakdown protection assembly.

FIG. 4 shows an embodiment where the cladded or treated areas 140 and 150 are shown where the tabs may be presoldered. The weld areas 102 are also shown to show where the attachment points are between the tabs 110 and 120 and the cell.

Optionally, for attachment of the tabs to the solar cell, some embodiments may use soldering in addition with or in combination with welding to attach the tabs 110 and 120 to the cell. It should be understood that the cell is such a heat sink that to quickly solder to cell requires a minimum tack time that will typically take several seconds. Using methods such as spot welding, 0.1 to 0.3 seconds tact time can be achieved. The large heat sink effect of the cells, while desirable once the die is attached, presents a challenge to achieving that attachment during assembly.

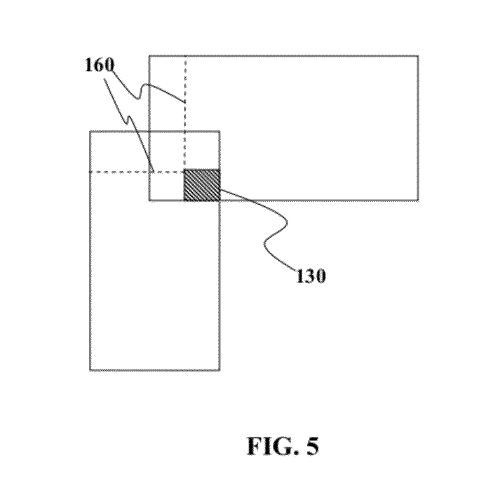

Referring to FIG. 5, this embodiment shows that the same tabs 110 and 120 may be configured for use even if the size of the breakdown protection device 130 is reduced. FIG. 5 shows that the overall size of the tabs and the area left for spot welding remains the same. The areas to be trimmed are indicated by dotted lines 160.

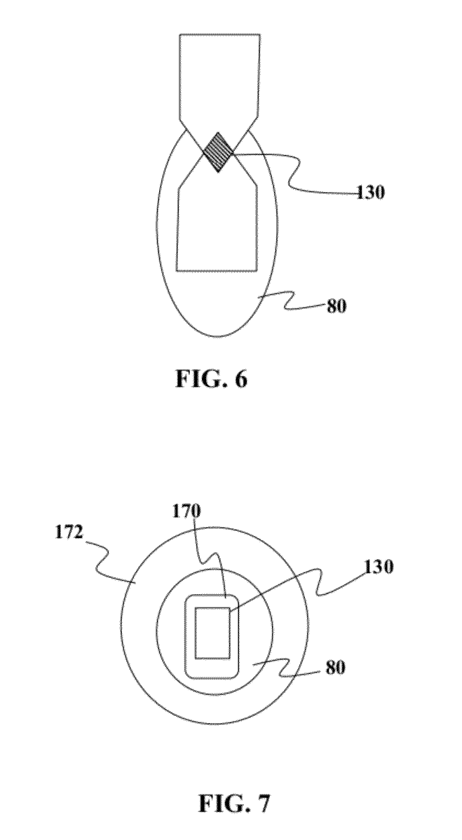

Referring now to FIG. 6, a still further embodiment is shown wherein the tabs are positioned at different orientations. The point of this embodiment is to overlap as little as possible, but that the diode is fully covered (top and bottom) for thermal and electrical reasons. There are some embodiments that have spacers that prevent overlap instead of or in combination with minimizing the overlap of the tabs that extend beyond the area of breakdown protection device 130.

Referring now to FIG. 7, yet another embodiment is shown wherein there is a smaller tab 170 on the underside of the device 130 and a larger circular tab 172 above the device 130. Again, laser welding, ultrasonic welding, and/or spot welding may be used to attach the tab to the cell.

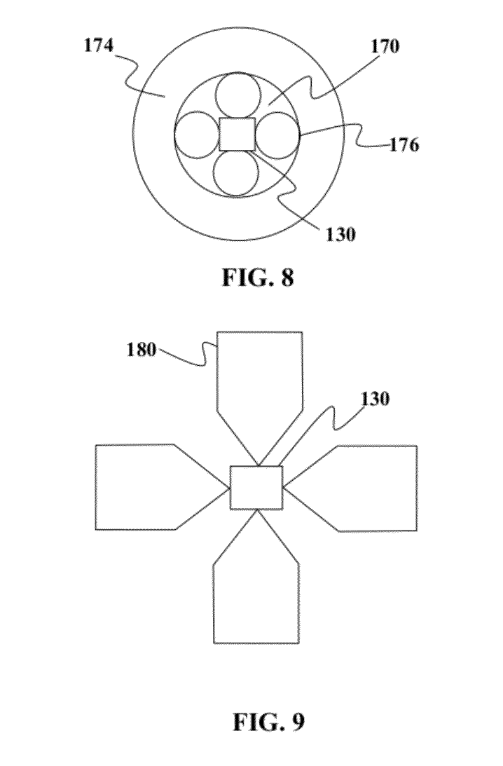

Referring now to FIG. 8, according to at least one embodiment of the present invention, a variation of the embodiment of FIG. 7 is shown wherein a larger circular tab 174 above the device 130 has openings 176 to allow for spot welding of the tab beneath the device 130. Again, laser welding and/or spot welding may be used to attach the tab to the cell.

Referring now to FIG. 9, according to at least one embodiment of the present invention, a butterfly embodiment is shown having four tabs 180 around the centrally located device 130. In this embodiment, the butterfly has a symmetrical design and all the forces are good during thermal cycling. However, it is found that it is the forces along the length of the tab can create shear for the solder joint and for the device 130. Thus, control of tab length can influence force build up in the tab, solder joints, or breakdown protection device 130. In most embodiments, the shorter the tab the better. The embodiment of the FIG. 3 is advantageous in that the stresses are minimized. The placement of the device 130 at the edge of the tab reduces force and the tabs as short as possible also reduces forces.

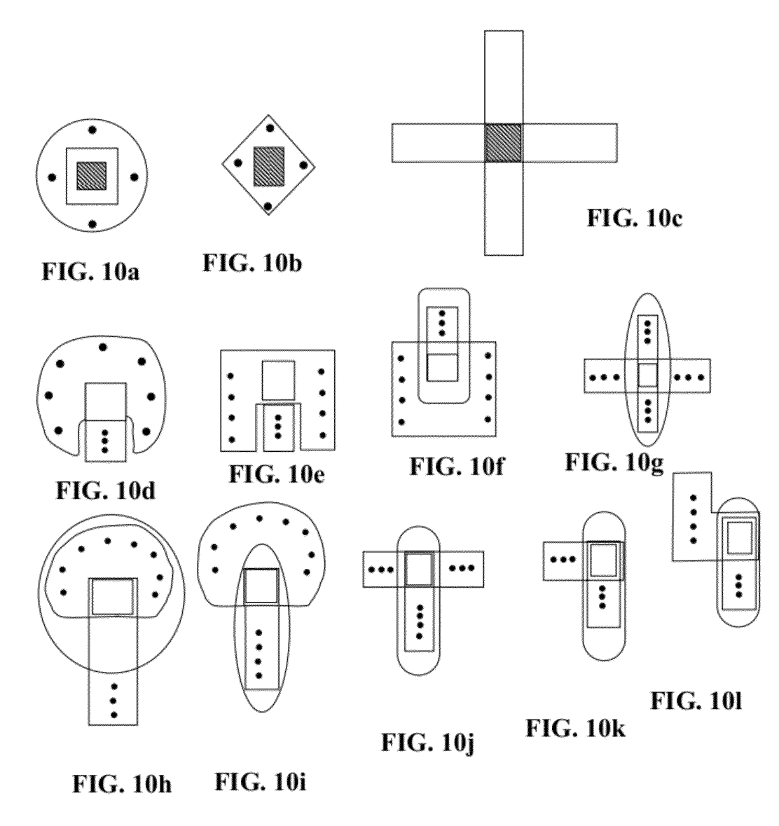

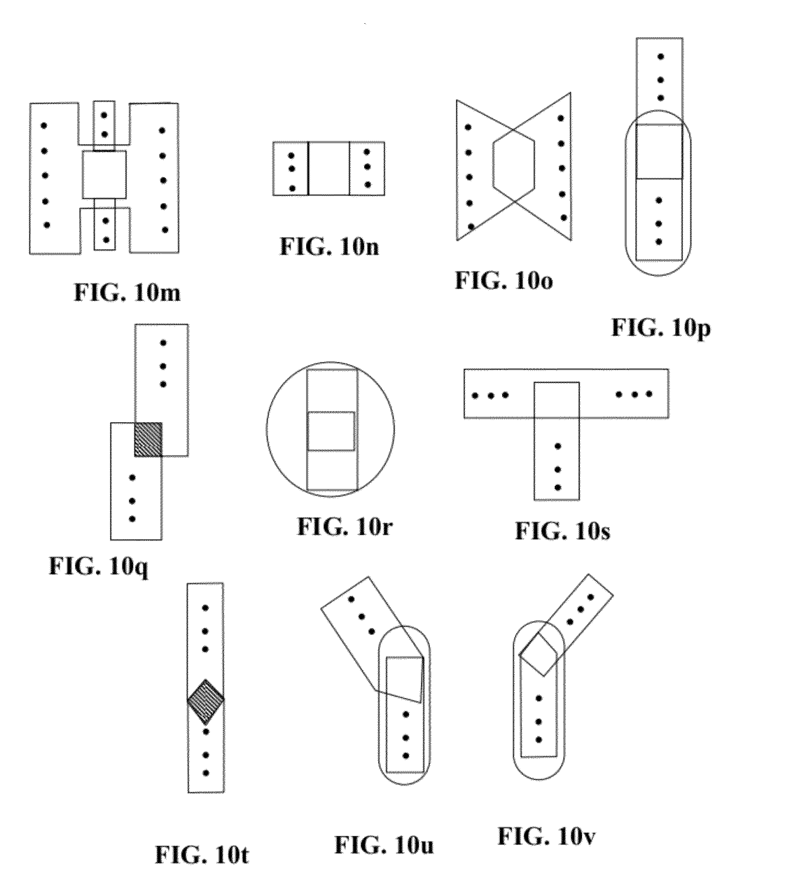

FIGS. 10a through 10v show a variety of other configurations wherein the breakdown protection device 130 is sandwiched between tabs of various shapes, orientations, cutouts, or the like. For example, FIG. 10a and other examples show that the tab can be used to create connections in multiple directions in the plane of the cell so as to balance the stress during thermal cycling. Some embodiments may have cutouts such as in FIG. 10d to allow for line of sight access to weld locations on the assembly 100. Some may only have attachment points in opposing axis, such as the upper tab outside the opening in FIG. 10J. FIG. 10m shows an upper tab with an H-configuration. FIG. 10o shows a tab with a bow-tie configuration.

### Method of Assembly

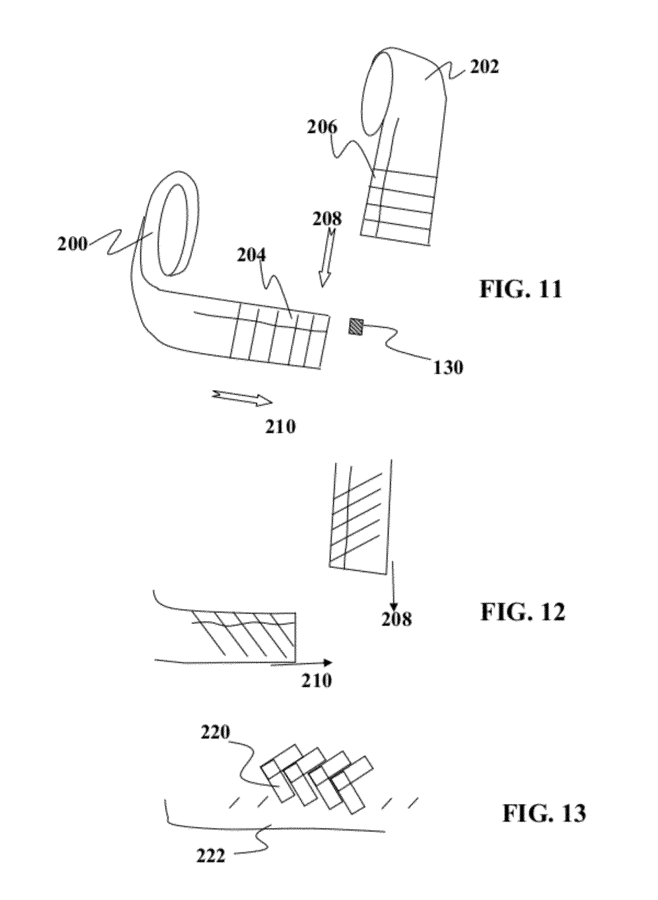

Referring now to FIGS. 11 to 17, according to at least one embodiment of the present invention, various methods and processes for manufacturing the breakdown protection assembly will now be described. It should be understood that the process may be a continuous, discontinuous, batch, or other type of process. For high throughput, a continuous process is typically used but the embodiments of the present invention are not limited to such a process.

FIG. 11 shows one embodiment wherein a continuous process is shown. If tab assembly to be produced in mass, two tabs that come in from separate reels 200 and 202. The reels may be clad in the areas 204 and 206 where the breakdown protection device 130 will be in contact with the tabs from each of the reels 200 and 202. The diode is brought in, either to one reel first or simultaneously between both reels as the materials from the reels meet. The material from the reels 200 and 202 are fed forward as indicated by arrows 208 and 210. The tabs from the reels are pressed together and then singulated. The reel material may be heated before, during, or after placement of the breakdown protection device 130. The heating may be by way of a heated roller, induction heating, infrared source, laser heating, or other thermal source. The material in each reel 200 and 202 may be pre-cut (but still attached at one or more attachment point to the rest of the reel) or the material may be uncut when on the reel and singulated at the time the materials from the two reels meet. Various marker or alignment holes may be used in the reel for any of the embodiments herein.

FIG. 12 shows an embodiment that is variation of the one shown in FIG. 11. This embodiment in FIG. 12 shows that the tabs in the reels may be angled backward (or forward) diagonally so that the mating of the two reels can place the tabs at a right angle orientation or at other orientation without having to change the line of travel of the reels.

FIG. 13 shows yet another embodiment wherein a number of tabs 220 are precut at an angle that allows for tabs from another reel, batch, or individuals to be attached to the material still on the reel 222. In this manner, the output is not a plurality of individual singulated breakdown protection assemblies, but a tape or reel 222 having a plurality of these completed “boomerang” shaped breakdown protection assemblies still attached thereon. This continuous tape may then be feed to a downstream device for final lamination, testing device to see which assemblies are functional, or a pick and place tool for delivery of the assembly to the final destination. Optionally, some embodiments may run two reels of tapes of together instead of using individual tabs together. This turns the process from a one reel to a two reel assembly process. One reel may already have the devices 130 on them. In some embodiments, it could be batches of tabs with many diodes or devices 130 on it

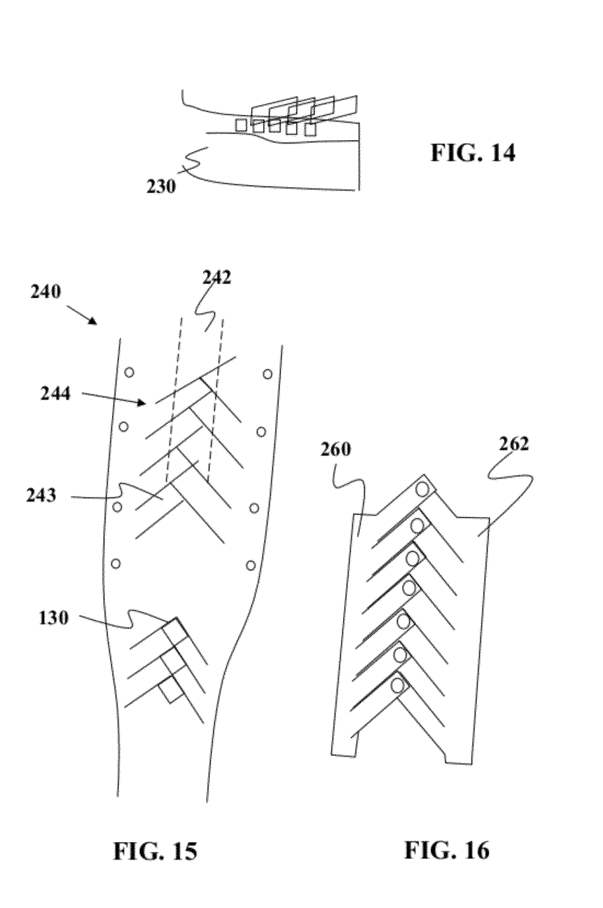

Referring now to FIG. 14, a still further embodiment of the present invention will now be described. This embodiment is similar to the embodiment of FIG. 13, except that the flags or tabs being added to the reel may overlap. This allows for variation in angle that the tabs are attached to the tabs on the reel 230.

Referring now to FIG. 15, at still further embodiment of the present invention is shown. This embodiment is distinguished in that it is a single reel embodiment that will contain both tabs to be used in the breakdown protection assembly. The center of the reel 240 may have the treated area 242 down the middle where the solder is placed. Some embodiments may have solder on both side of the reel so that the appropriate side of each tab is solder treated. Some may have the solder specifically configured to be only at locations 243.

As see in FIG. 15, a fishbone, staggered chevron, or angled precuts 244 are made into the material of the reel 240. This may substantially show the outline of the final assembly. The pre-cut leaves one or more attachment points so that the material remains secured to the reel. In one embodiment, this can be a rotating die, wherein once done cutting, the breakdown protection device is placed in the target area and then one or both of the tabs are then slightly overlapped. In some embodiments, this overlapping may having the center areas cut one more time to allow for the tabs to be moved together. Optionally, no additional cut is made and the two tabs are forced to overlap based on narrowing of the reel. In one embodiment, the overlap may be in the range of about 1 mm to about 3 mm. Optionally, the overlap may be in the range of about 0.5 mm to about 5 mm.

This overlap (by one or both tabs) results in a “zipper” action wherein the center areas are brought together. Into the overlap one can squeeze in the diode or device 130. Or, as previously mentioned, some may put the diode on first, then overlap and press together.

Referring now to FIG. 16, according to at least one embodiment of the present invention, it should be understood that some embodiments could be by batch wherein the system will stamp out a comb 260 of material, put diodes on, then take same comb, flip it, press it down on another comb 262. Optionally, instead of having to flip one of the combs, the two combs 260 and 262 are merged together so that one slides over the other to achieve the correct orientation and overlap for assembly.

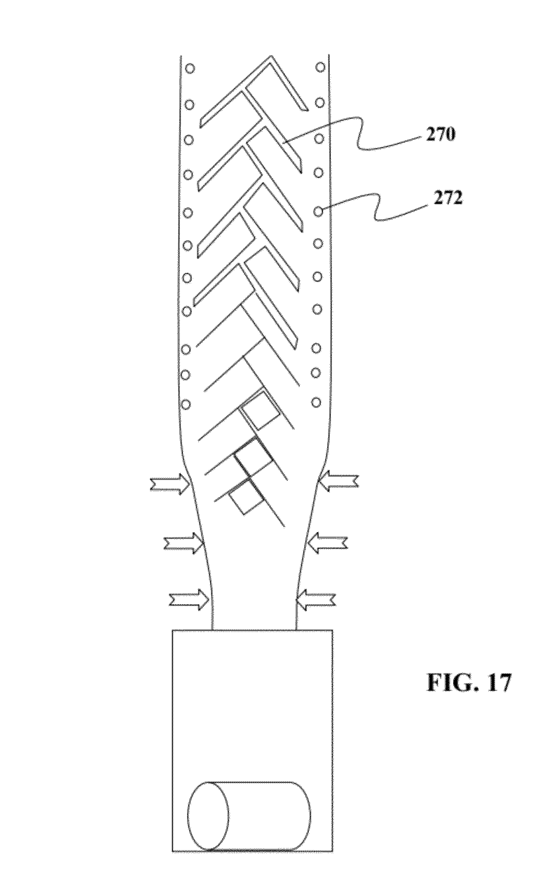

Referring now to FIG. 17, according to at least one embodiment of the present invention, yet another angle is shown of the embodiment of FIG. 15 wherein the cutout 270 is more clearly shown. The reel 240 could have breakaways built in that are pressed down to sever it into the assembly. A variety of registration holes or marks 272 may also be used. After assembly, the entire roll may be sent for testing to determine which diodes or devices 130 survived lamination. The reel 240 may be re-rolled into a compact roll configuration or kept in linear strip that may or may not be cut to form shorter reels. Optionally, some may singulate the assembly versus keeping it on a reel. Some may chop, insert diode, put other tab on, and put on a heated roller to assemble. Some embodiments may configured so that after the diode is inserted, the system will punch both tabs out and soldered the assembly to the cell.

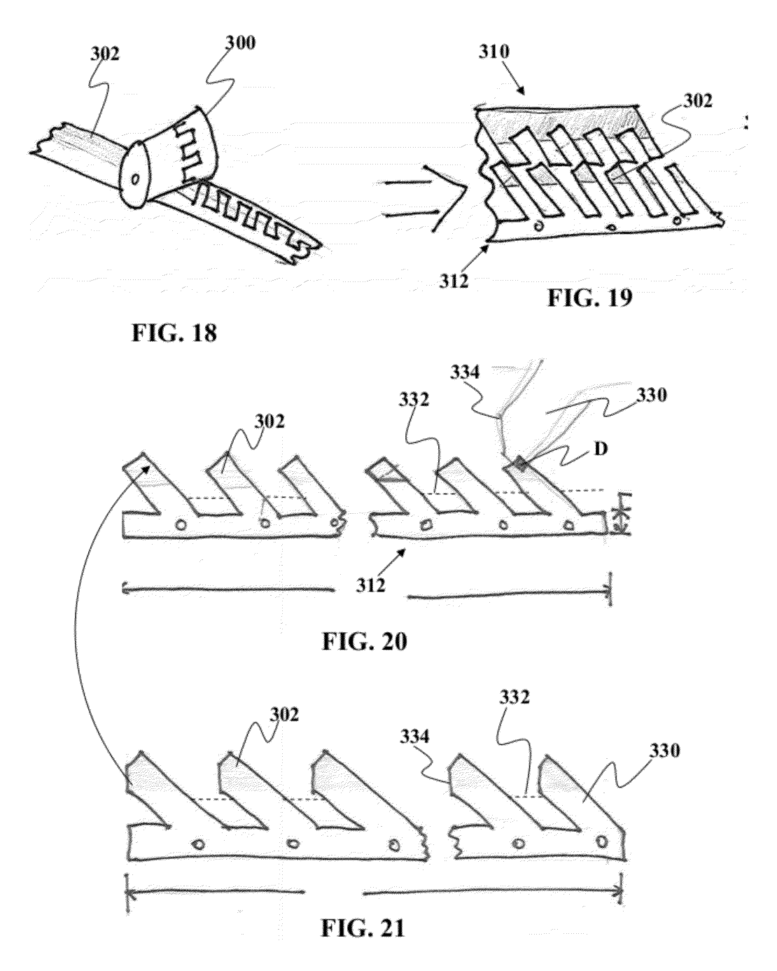

Referring now to FIG. 18, another embodiment of the present invention shows a cutting wheel 300 that may be used to create the two separate pieces or combs 310 and 312 shown in FIG. 19. The material being cut or optionally scored by wheel 300 may have a material 302 deposited in the areas where the diode or other device to be packaged will be positioned. That material 302 may be applied as a strip, in a pattern, or only at select locations. By way of nonlimiting example, the material 302 may be solder, solder paste, a metal coating that is compatible with soldering, welding or other electrically conductive joining techniques. These may be in long continuous rolls or reels. Optionally, the resulting pieces 310 or 312 may be cut into shorter discrete units which may have in one nonlimiting example from 5-20 “fins” that can joined together. The portion 310 may be used as scrap or it maybe scored so that it can also be used

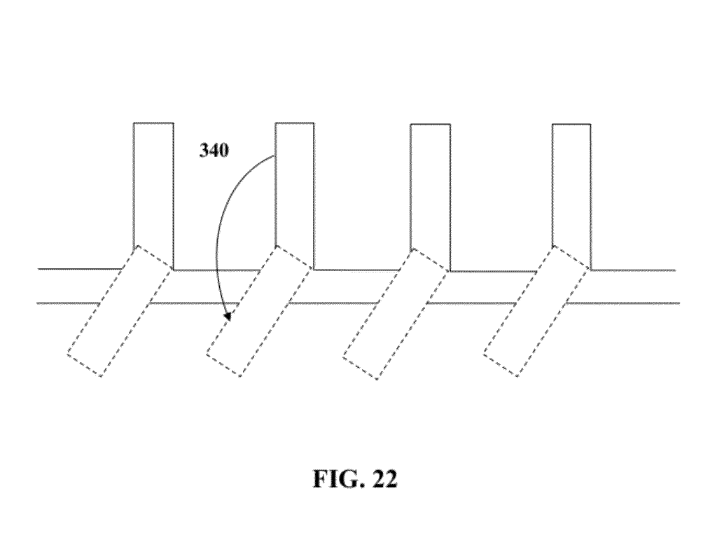

Referring now to FIG. 20, according to at least one embodiment of the present invention, this embodiment shows that the strip 312 where the device D will be placed between it and another comb 330 shown in FIG. 21. This sandwich structure creates two tabs at angles between 0 and 180 degrees, typically between 45 and 135 degrees. Optional support connectors 332 may be left between fins on the comb. This may be for structural support or other manufacturing reasons. Alignment holes or registration holes may also be incorporated into each comb.

FIG. 21 shows an embodiment wherein the ends 340 of the comb 330 has a different shape. The trimmed off portion 334 allows for a smaller final packaging when combined with the comb 312 in FIG. 20. The width of each fin in the comb 330 may also be wider to accommodate greater contact with the solar cell in the final assembled device.

FIG. 22 shows a still further embodiment wherein creating a comb with fins at 45 degrees or other angles can be achieved by first creating a plurality of straight orthogonally aligned fins which are then folded over as indicated by arrow 340 to create the desired packaging.

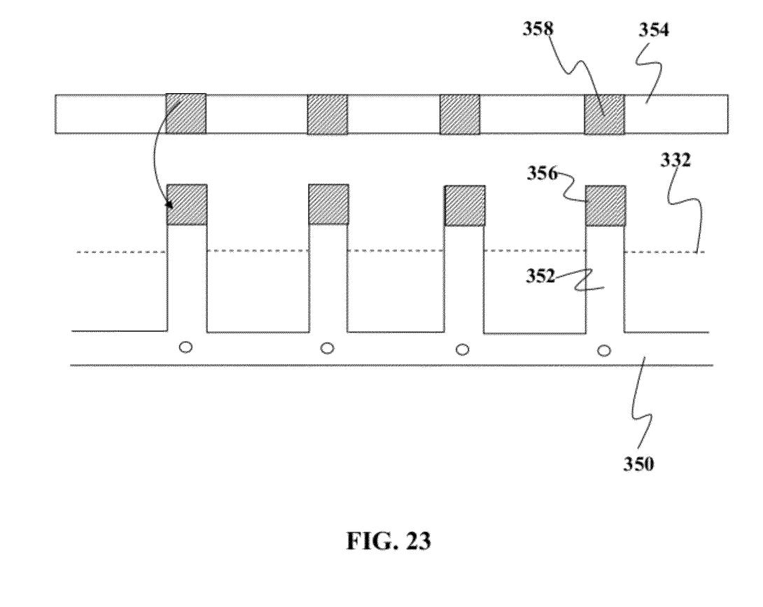

FIG. 23 shows a still further embodiment of the present invention wherein a first comb 350 of orthogonally oriented fins 352 is mated with a linear strip 354 that will be jointed over the area 356 that is treated to allow for electrically conductive attachment to a device D between the areas 356 and 358. The joined structure may in batches of multiple combs or may be continuous combs. These are later singulated by slitters or other cutting devices to create a plurality of individual assemblies having a tab or fin, the device D, and another tab or fin over the device D.

It should be understood that a variety of post assembly processing such as but not limiting testing, further heating to improve solder contact, or the like may be used after the breakdown protection device is placed into the assembly.

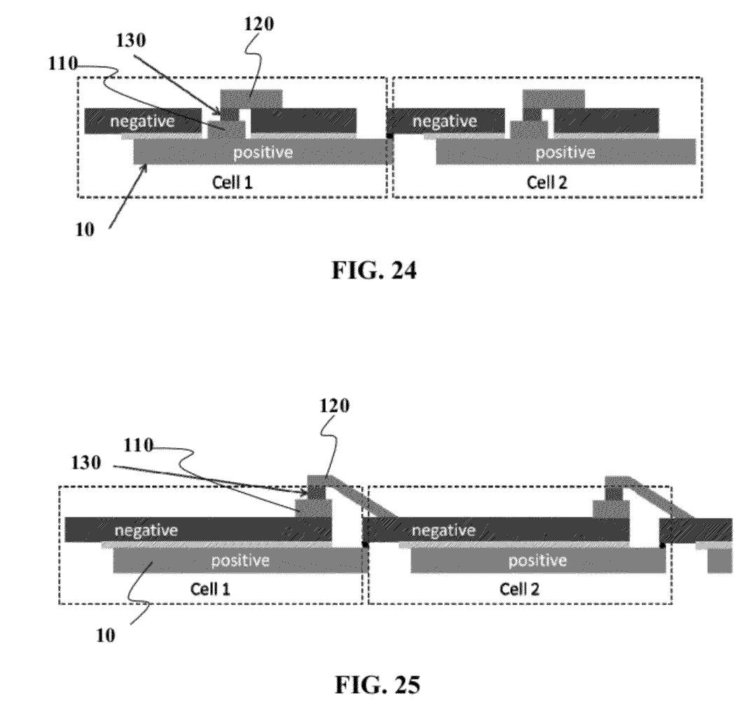

Referring to FIGS. 24 and 25, the position of the assembly 100 can also be varied to be completed on one cell, or as part of the interconnection between cells. For connection to the cell, all of the following options are adaptable for use: welding (all forms, including laser, conduction, resistance, ultrasonic, all types of electrical arc, etc. . . . ), brazing soldering, adhesive and non-adhesive electrically conductive interface materials (pastes, greases, epoxies, particles), and/or surface pressure contact. Although positive and negative are labeled in the figures, it should be understood that they can be reversed in alternative embodiments.

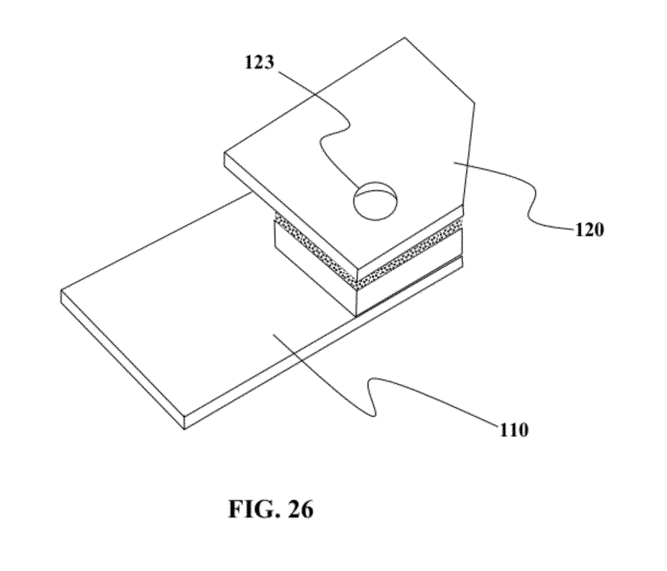

Referring to FIG. 26, according to at least some embodiments of the present invention, the tabs 110 and 120 can have some material removed in the area 123 to be soldered to allow for gases to escape during the soldering process. Some embodiments can have area 123 be at locations where voids can form between the joint from the die to the tab.

Optionally, the total thickness of the tabs 110 and 120 is minimized to allow for CTE mismatch between tabs, solder and die without over-stressing the die or solder and preventing the creation of cracks in the die or solder during manufacture and operation of the butterfly diode assembly. The tab thicknesses and material properties can be selected to exert low force on the solder joint and die with or without the tabs reaching stresses above the tab material yield stress. In one case, the tabs 110 and 120 have material thickness (with or without solder) in the range of 0.001 mm to 0.100 mm, depending on tab, solder and die materials.

Optionally, the solar cell acts as a heat sink during the diode operation. In this assembly, this embodiment has created a power diode which high current capability (10 amps or more) that has heat sinks on both sides (top and bottom) which is also unusual. Optionally, some embodiments may have at least 5 amp rating on the diode.

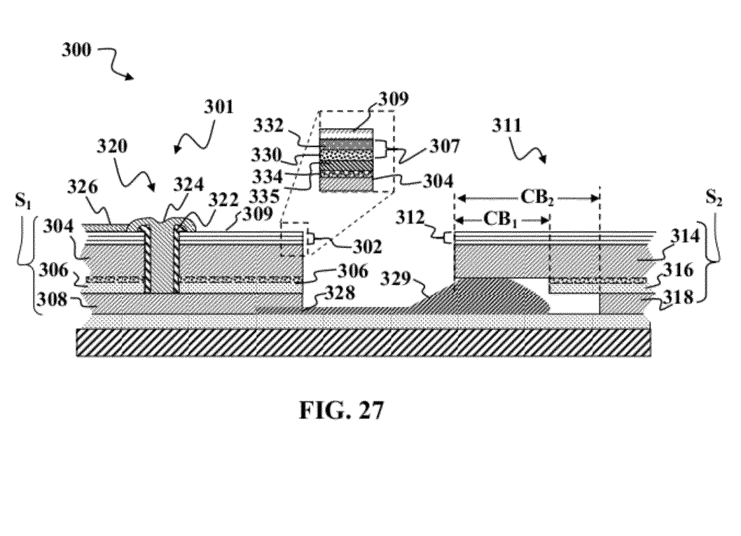

Referring to FIG. 27, one embodiment of a solar cell architecture for use with the present invention will now be described. U.S. Patent Application 20060157103 is fully incorporated herein by reference for all purposes. the first device module 301 may be attached to the carrier substrate 303 such that the back plane 308 makes electrical contact with the thin conducting layer 328 while leaving a portion of the thin conducting layer 328 exposed. Electrical contact may then be made between the exposed portion of the thin conducting layer 328 and the exposed portion of the bottom electrode 314 of the second device module 311. For example, a bump of conductive material 329 (e.g., more conductive adhesive) may be placed on the thin conducting layer 328 at a location aligned with the exposed portion of the bottom electrode 314. The bump of conductive material 329 is sufficiently tall as to make contact with the exposed portion of the bottom electrode 314 when the second device module 311 is attached to the carrier substrate. The dimensions of the notches 317, 319 may be chosen so that there is essentially no possibility that the thin conducting layer 328 will make undesired contact with the back plane 318 of the second device module 311. For example, the edge of the bottom electrode 314 may be cut back with respect to the insulating layer 316 by an amount of cutback CB₁ of about 400 microns. The back plane 318 may be cut back with respect to the insulating layer 316 by an amount CB₂ that is significantly larger than CB₁. Optionally, 329 can be alternatively be configured to be part of the foil and being extend in the manner as shown in FIGS. 25 and 26 to form a connection and welded (laser, ultrasonic, etc. . . . ) to an adjacent cell.

The device layers 302, 312 are preferably of a type that can be manufactured on a large scale, e.g., in a roll-to-roll processing system. There are a large number of different types of device architectures that may be used in the device layers 302, 312. By way of example, and without loss of generality, the inset in FIG. 11 shows the structure of a CIGS active layer 307 and associated layers in the device layer 302. By way of example, the active layer 307 may include an absorber layer 330 based on materials containing elements of groups IB, IIIA and VIA. Preferably, the absorber layer 330 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. No. 6,268,014, issued to Eberspacher et al on Jul. 31, 2001, and US Patent Application Publication No. US 2004-0219730 A1 to Bulent Basol, published Nov. 4, 2004, both of which are incorporated herein by reference. A window layer 332 is typically used as a junction partner between the absorber layer 330 and the transparent conducting layer 309. By way of example, the window layer 332 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A layer 334 of a metal different from the bottom electrode may be disposed between the bottom electrode 304 and the absorber layer 330 to inhibit diffusion of metal from the bottom electrode 304. For example, if the bottom electrode 304 is made of aluminum, the layer 334 may be a layer of molybdenum. This may help carry electrical charge and provide certain protective qualities. In addition, another layer 335 of material similar to that of layer 103 may also be applied between the layer 334 and the aluminum layer 304. The material may be the same as that of layer 103 or it may be another material selected from the set of material listed for layer 103. Optionally, another layer 337 also be applied to the other side of layer 304. The material may be the same as that of layer 335 or it may be another material selected from the set of material listed for layer 103. Protective layers similar to layers 335 and/or 337 may be applied around the foil on any of the embodiments described herein.

Some embodiments can use diodes selected from one or more the following:

| | | | | |
|---|---|---|---|---|
| Current (A) | >10 | 10 | 10 | 2 |
| Thickness (um) | 150 | 1000 | 250 | 500 |

Typical lamination temperatures of 150-170 C and lamination times of 1-15 minutes are adequate to laminate the module as well as cure the conductive adhesives to achieve the proper electrical integration of the bypass diode devices into the module. It should be noted that this approach of applying the conductive adhesive first and curing it during.

Linearly placed bypass diode devices may be placed at any location over the back or bottom surface of the solar cells, including right over the conductive ribbons. Some embodiments may use thermally conductive adhesives include but are not limited to products sold by Resinlab (such as product No. EP 1121, which forms a flexible layer as desired in this application) and Dow Corning (such as product Nos. SE4450, 1-4173, and 3-6752). Thermally conductive transfer tapes provided by 3M company are also appropriate for this application

Some embodiments may have by-pass diodes for every three cells, every two cells or even every cell for safe and efficient operation. As used herein, the term “substantially congruent” means that the shape and size of a complementary cutout is about the same, within manufacturing tolerances for fabricating the complementary cutout, as the shape and size of a gap region when the complementary cutout is superimposed on the gap region. In cell architecture through an opening, wherein base of diode is not directly connected to the cell, but to a tab and then to a cell so that the surface tab directly beneath the die and facing the cell layer is free floating and thus can minimizing stress concentration.

The typical thickness of the active diode region 501 may be in the range of 0.05-0.3 mm, which thickness includes both the p-type semiconductor layer and the n-type semiconductor layer. The width of the leads may be in the range of 1-10 mm depending on the current rating of the module within which the bypass diode devices D would be employed. The typical width of the leads may be in the range of 2-6 mm. Since the bypass diode devices D are placed on the bottom or back, un-illuminated side of the solar cells or the circuit, wide leads do not contribute to any power loss from the module.

Thus, bypass diodes placed over the back surface of the metallic substrates of the solar cells may be thermally coupled to the solar cell substrates and any heat generated by the bypass diode can easily be dissipated to the large area solar cell and eventually to outside of the module. This also allows usage of bypass diodes that are sized to correspond to the module current rating, or some small percentage greater than the module current rating for reliability reasons, such as 10% or 20% larger. It should be noted that the typical size of the solar cells made on flexible substrates as described herein are larger than about 100 cm², whereas the typical size of the bypass diodes that correspond to the module current rating is less than 0.5 cm2. Therefore, the cell provides excellent heat sink properties to the bypass diode. This increases the long term reliability of the module.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it should be understood that they are not limited to incorporation only on the backside of the solar. Some may incorporate the diode or breakdown protection device on the side or the front of the solar cell. In one embodiment, a group IB-IIIA-VIA or other material maybe used as the voltage breakdown protection device. This device maybe used with a photovoltaic material made of the same material (in the same or different molar percentages). Optionally, thin-film material may be used as breakdown protection for silicon or other types of photovoltaic devices. Some embodiments may use just a single tab embodiment, not a dual tab. Some may use a corner placement of diode. Optionally, stress is absorbed by the tab, not the welds (based on but not limited to thickness reduction and CTE matching material to the heat sink layer(s)). Optionally, creating a multi layer assembly with a bare die having a yield member that is also an electrical connector and thermal connector. Optionally, using a void prevention element in the tab architecture. As used herein, the term “substantially rectangular shape” means that the shape is that of a rectangle within manufacturing tolerances for fabricating a rectangular shape. Some embodiment can use tabs with one or more the following layers: copper strip, Cu, plated with tin, Sn, or nickel, Ni. Optionally, non-height, non lateral space taking configuration is sued for the die placement.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, copper-indium-gallium-selenium (for CIGS solar cells), CdSe, CdTe, ZnTe, CdZnTe, Cu(In,Ga)(S,Se)₂, Cu(In,Ga,Al)(S,Se,Te)₂, other absorber materials, IB-IIB-IVA-VIA absorbers, or other alloys and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. Nos. 11/207,157 filed Aug. 16, 2005 and 12/064,031 filed Aug. 16, 2006 are fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A thin film solar cell with electrical breakdown protection.

2. The device of claim 1 comprising:
a non-elongated, non-silicon thin-film solar cell using an electrically conductive foil substrate wherein the foil substrate carries current when the cell is forward biased, the substrate having a ratio of width to length greater than about 0.5 along an axis of current flow, and when exposed to light at AM 1.5G, the solar cell has an Impp greater than about 4 amps;
an avalanche breakdown protection assembly to prevent the avalanche breakdown at the one or more locations by directing current through the protection unit.

3. The device of claim 1 comprising: in solar cell diode

4. The device of claim 1 comprising:
packaging with top and bottom heat sink connectors, wherein the heat sinks are different layers of the same cell.

5. The device of claim 1 comprising:
packaging with top and bottom heat sink connectors, wherein the heat sinks are different layers of different cells.

6. The device of claim 1 comprising:
a total vertical height is about 180 to 500 microns or less

7. The device of claim 1 comprising:
stack height is about 300 to 400 microns or less

8. The device of claim 1 comprising:
a first area that is provided with a first material and a second area that is provided with a second material, wherein the first and second materials are different from one another, and wherein the first and second materials are selected from (a) materials that are electrically conductive, (b) materials that do not bond well to each other, (c) an interface material therebetween
said composition at least partially filling a cavity on the tab

9. The device of claim 1 comprising:
a device for implantation in a solar cell comprising a diode, a first heat sink attachment having a triggerable adhesive property that allows the implantable device to adhere when exposed to a stimulus.

10. The device of claim 1 comprising:
a tab having a bulk sub-region beneath the surface is activated to be become a solderable joint forming area and another area that is not substantially coated and not solderable when activated.

11. A method of breakdown protection assembly comprising:
providing a single reel of material which is pre-cut in a pattern so that a first portion of the material can be overlapped to a second portion of material to sandwich a breakdown protection device therebetween.
